(19) United States
(12) Patent Application Publication
(10) Pub. No.: US 2009/0207573 A1
(43) Pub. Date: Aug. 20, 2009

(54) ELECTRONIC MODULE COMPRISING MOUNTING TAGS

(75) Inventors: Kim Leng Soh, Singapore (SG); Tuncay Buekrue, Duisburg (DE); Klaus Barth, Neukirchen-Vluyn (DE); Johannes Josephus Maria Van Daal, Waalre (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 11/911,526

(22) PCT Filed: Apr. 7, 2006
(86) PCT No.: PCT/IB06/51074

§ 371 Date: Mar. 9, 2009

(30) Foreign Application Priority Data
Apr. 12, 2005 (EP) 05102876.9

(51) Int. Cl. H05K 7/02; H05K 13/04

(52) U.S. Cl. 361/760; 29/428

(57) ABSTRACT

An electronic module MO2 comprises a housing (1) within which an electronic circuit (2) resides, and a mounting tag (15) for mounting the electronic module MO2 on a printed circuit hoard PCB. The mounting tag (15) comprises, from an end towards the housing, a first portion (15A), a second portion (15B) and a third portion (15C). The first portion (15A) has a first width inferior to a second width of the second portion (15B) so as to define a first abutment (16A). The first abutment will come into contact with a printed circuit board PCB when the mounting tag (15) is inserted in a hole (18) of that printed circuit board having a hole width comprised between the first width and the second width. The second width of the second portion 15B is inferior to a third width of the third portion (15C) so as to define a second abutment (16B). The second abutment will come into contact with a printed circuit board PCB when the mounting tag (15) is inserted in a hole (19) of that printed circuit board having a hole width comprised between the second width and the third width.

### FIELD OF THE INVENTION

An aspect of the invention relates to an electronic module comprising mounting tags. The electronic module may be, for example, a radiofrequency (RF) tuner module which may be mounted on a printed circuit board.

Another aspect of the invention relates to an electronic apparatus comprising an electronic module comprising mounting tags. For example, a RF tuner module may be fitted within a variety of consumer electronic apparatuses like television, set-top-box, multimedia card for computer, etc.

A further aspect of the invention relates to a method of manufacturing an electronic apparatus.

### BACKGROUND OF THE INVENTION

FIGS. 1, 2.A and 2.B schematically illustrate a known RF tuner module.

A RF tuner module MO1 comprises a housing, e.g. a stamped metal frame 1, an electronic circuit 2, a RF connector 3, a plurality of printed circuit board connecting pins 4 and a plurality of mounting tags 5, 5′. The electronic circuit 2 schematically illustrated by dotted line is internally housed within the stamped metal frame 1. The RF connector 3 is a standard RF connector well known in the field of television application. The RF tuner module may comprise additional connectors (not shown). The plurality of printed circuit board connecting pins 4 are I/O pins. The plurality of mounting tags 5, 5′ are provided on the stamped metal frame 1. For example, four mounting tags may be provided on each corner of the stamped metal frame 1. It should be noted that solely two of them are shown in the Figures. Each mounting tag has a step like shape. For example, the mounting tag 5 comprises a first portion 5A and a second portion 5B. The first portion 5A has a reduced width relatively to the second portion 5B, so as to define two abutments 6A, 6B.

When horizontally mounting a RF tuner module MO1 onto a printed circuit board PCB, each I/O pins 4 is inserted in a matching footprint 7 of the printed circuit board PCB, while each mounting tag 5 is inserted in a position adjusting hole 8 of the printed circuit board PCB. The position adjusting holes 8 enable a correct positioning of the RF tuner module onto the printed circuit board surface. The mounting tags 5 inserted into the hole enable a reliable mechanical supporting of the RF tuner module by the printed circuit board.

The position adjusting hole 8 has a diameter which substantially corresponds to the width of the first portion 5A of the mounting tag 5. Thus, the insertion of the mounting tag 5 and I/O pins into the printed circuit board PCB is stopped when the abutments 6A, 6B come into contact with the printed circuit board top surface.

Hence, the mounting tag 5 determines a first height Hi corresponding to the gap between the printed circuit board top surface and the RF tuner module MO1 back surface, a second height H2 corresponding to the overall height of the RF tuner module MO1 above the printed circuit board PCB, and a third height H3 corresponding to the height between the printed circuit board top surface and the horizontal central axis of the standard RF connector 3.

Due to the various applications of the RF tuner module, compatibility or standardization reasons, the different heights H1, H2 or H3 may vary. Each application with different heights requires a different set of mounting tags, thus different electronic modules. Each RF tuner module having its own dimension adapted to a particular application, the RF tuner module has the drawback from the manufacturer and customer perspective of increasing the cost due to the important electronic module diversity.

### SUMMARY OF THE INVENTION

It is an object of the invention to propose an electronic module comprising mounting tags that overcomes at least one of the drawbacks of the prior art electronic modules.

According to an aspect, the invention relates to an electronic module comprising:
a housing within which an electronic circuit resides,
a mounting tag for mounting the electronic module on a printed circuit board (PCB),
the mounting tag comprises, from an end towards the housing, a first portion, a second portion and a third portion,
the first portion has a first width inferior to a second width of the second portion so as to define a first abutment, which will come into contact with a printed circuit board when the mounting tag is inserted in a hole of that printed circuit board having a hole width comprised between the first width and the second width, and
the second width of the second portion is inferior to a third width of the third portion so as to define a second abutment, which will come into contact with a printed circuit board when the mounting tag is inserted in a hole of that printed circuit board having a hole width comprised between the second width and the third width.

According to a further aspect, the invention relates to an electronic apparatus comprising an electronic module having at least one mounting tag according to the invention and a printed circuit board, the electronic module being horizontally mounted onto the printed circuit board.

According to still a further aspect, the invention relates to a method of manufacturing an electronic apparatus comprising the step of:
a) providing an electronic module, the electronic module comprising:
   a housing within which an electronic circuit resides and a mounting tag, the mounting tag comprises, from an end towards the housing, a first portion, a second portion and a third portion,
   the first portion has a first width inferior to a second width of the second portion so as to define a first abutment, and
   the second width of the second portion is inferior to a third width of the third portion so as to define a second abutment,
b) mounting the electronic module onto a printed circuit board by:
   b1) inserting the mounting tag in a hole of that printed circuit board having a hole width comprised between the first width and the second width until the first abutment come into contact with a top surface of that printed circuit board when manufacturing an electronic apparatus having a first characteristic dimension,
   b2) inserting the mounting tag in a hole of that printed circuit board having a hole width comprised between the second width and the third width until the second abutment come into contact with a top surface of that printed circuit board when manufacturing an electronic apparatus having a second characteristic dimension.

The first characteristic dimension may be a first gap height between the electronic module and the printed circuit board. The second characteristic dimension may be a second gap height between the electronic module and the printed circuit board.

Alternatively, the first characteristic dimension may be a first connector height. The second characteristic dimension may be a second connector height.

The invention allows a horizontally mounted RF tuner module to have at least two different mounting heights. The width of holes for receiving the mounting tags on the printed circuit board determines the mounting heights.

Thus, the invention is particularly well adapted for reducing the manufacturer and customer electronic module diversity. More precisely, a single electronic module can be applied in numerous different applications, e.g. television, multimedia printed circuit board, each application requiring a different mounting height. Decreasing the diversity of electronic modules further helps in reducing the cost due to the logistic of the frames, the number of tool equipment, the number of punching machine, etc . . .

As a further example, it may be desirable to have a lowest possible mounted electronic module profile over a printed circuit board. In this case, the printed circuit board is provided with holes for receiving the mounting tags of a large size that will determine a reduced gap height when the electronic module of the invention is mounted.

As another example, it may be desirable to accommodate others components below the electronic module (multi-layer printed circuit board). In this case, the printed circuit board is provided with holes for receiving the mounting tags of a small size that will determine an important gap height when the electronic module of the invention is mounted.

These and other aspects of the invention will be apparent from and elucidated with reference to the embodiments described hereinafter.

### BRIEF DESCRIPTION OF THE DRAWINGS

The present invention is illustrated by way of example and not limited to the accompanying figures, in which like references indicate similar elements:

FIG. 1 is a perspective top view which schematically illustrates a mount-tag of a RF tuner module according to the prior art;

FIG. 2.A is a side view which schematically illustrates the mount-tag of a RF tuner module of FIG. 1 according to the prior art;

FIG. 2.B is an enlarged and partial side view which schematically illustrates the mount-tag of a RF tuner module of FIG. 2 coupled to a printed circuit board according to the prior art;

FIG. 3 is an enlarged and partial side view which schematically illustrates a mount-tag of a RF tuner module for dual stand-off coupled to a printed circuit board, in a first configuration, according to the invention; and

FIG. 4 is an enlarged and partial side view which schematically illustrates a mount-tag of a RF tuner module for dual stand-off coupled to a printed circuit board, in a second configuration, according to the invention.

### DETAILED DESCRIPTION OF THE INVENTION

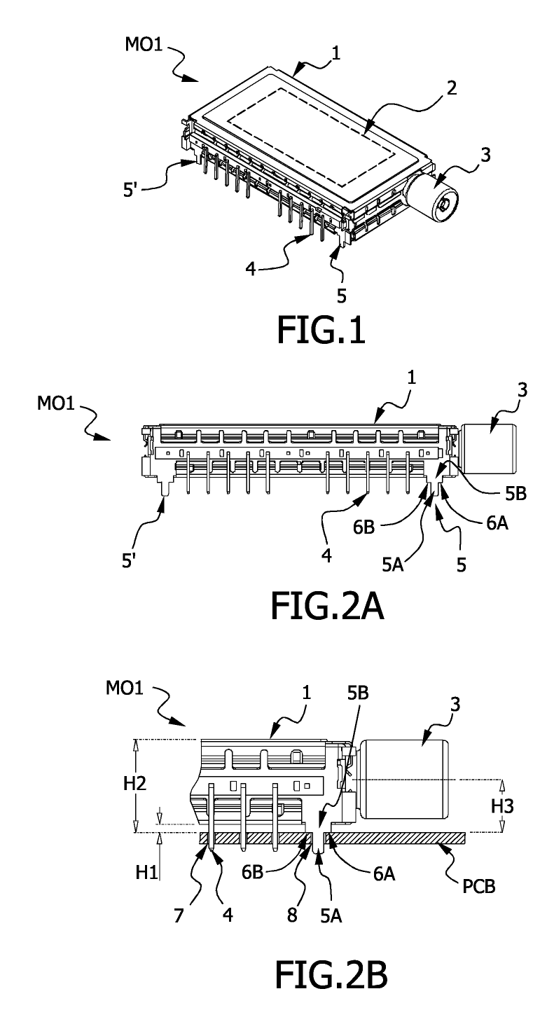

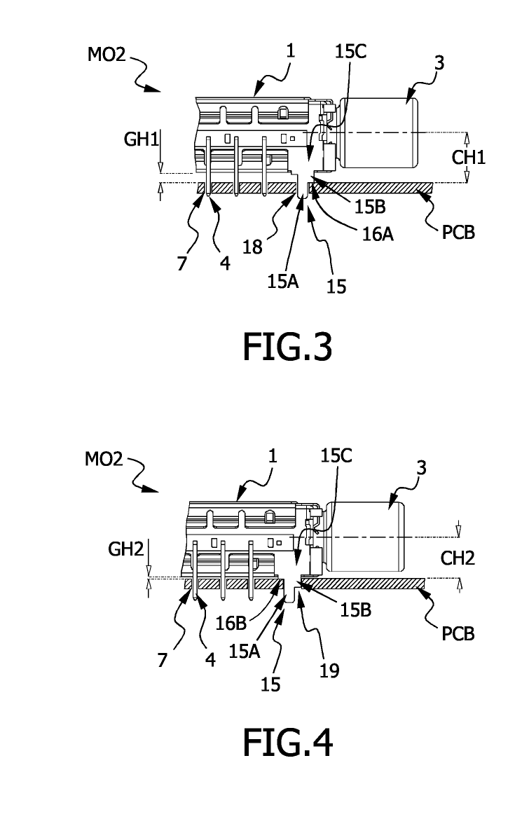

FIGS. 3 and 4 are partial views schematically illustrating an RF tuner module MO2 mounted on a printed circuit board PCB according to the invention. Further, it is to be noted that the RF tuner module MO2 is substantially similar to the RF tuner module MO1 shown in FIG. 1 except for the mounting tag.

The RF tuner module MO2 comprises a housing, e.g. a stamped metal frame 1, an electronic circuit (not shown), a RF connector 3, a plurality of printed circuit board connecting pins 4 and a plurality of dual stand-off mounting tags 15. The electronic circuit is internally housed within the stamped metal frame 1. The RF tuner module MO2 may comprise additional connectors (not shown). The plurality of printed circuit board connecting pins 4 are I/O pins. The plurality of dual stand-off mounting tags 15 are provided on the stamped metal frame 1, for example 4 mounting tags are provided on each corner of the stamped metal frame 1. Each dual stand-off mounting tag has a dual steps like shape. The dual stand-off mounting tag 15 comprises a first portion 15A, a second portion 15B and a third portion 15C. The first portion 15A has a width inferior to the second portion 15B so as to define a first abutment 16A. The second portion 15B has a width inferior to the third portion 15C so as to define a second abutment 16B.

The mounting tag 15 is substantially vertical relatively to the printed circuit board that is substantially horizontal. Advantageously, the first abutment 16A and the second abutment 16B are substantially parallel to the printed circuit board top surface.

FIG. 3 shows a RF tuner module MO2 mounted onto a printed circuit board PCB, in a first configuration.

When horizontally mounting a RF tuner module MO2 onto a printed circuit board PCB, each I/O pins 4 is inserted in a matching footprint 7 of the printed circuit board PCB, while each mounting tag 15 is inserted in a first associated receiving hole 18 of the printed circuit board PCB.

The first associated receiving hole 18 has a width which is comprised between the first portion width and the second portion width. Advantageously, the receiving hole 18 width substantially corresponds to the width of the first portion 15A of the mounting tag 15. Thus, the insertion of the mounting tag 15 and I/O pins into the printed circuit board PCB is stopped when the first abutments 16A comes into contact with the printed circuit board top surface.

In this first configuration, the mounting tag 15, in particular the first portion 15A, and the first receiving hole 18 width determines a first gap height GH1 corresponding to the gap between the printed circuit board top surface and the RF tuner module MO2 back surface, and a first connector height CH1 corresponding to the height between the printed circuit board top surface and the horizontal central axis of the standard RF connector 3.

FIG. 4 shows a RF tuner module MO2 mounted onto a printed circuit board PCB, in a second configuration.

When horizontally mounting a RF tuner module MO2 onto a printed circuit board PCB, each I/O pins 4 is inserted in a matching footprint 7 of the printed circuit board PCB, while each mounting tag 15 is inserted in a second associated receiving hole 19 of the printed circuit board PCB.

The second associated receiving hole 19 has a width which is comprised between the second portion width and the third portion width. Advantageously, the receiving hole 19 width substantially corresponds to the width of the second portion 15B of the mounting tag 15. Thus, the insertion of the mounting tag 15 and I/O pins into the printed circuit board PCB is stopped when the second abutments 16B comes into contact with the printed circuit board top surface.

In this second configuration, the mounting tag 15, in particular the second portion 15B, and the second receiving hole 19 width determines a second gap height GH2 corresponding to the gap between the printed circuit board top surface and the RF tuner module MO2 back surface, and a second connector height CH2 corresponding to the height between the printed circuit board top surface and the horizontal central axis of the standard RF connector 3.

The holes 18 or 19 into the printed circuit board PCB may be bores or slots.

Thus, with the electronic module comprising the mounting tags of the invention, it is possible to define two different gap heights and/or two different connector heights with a single electronic module and associated printed circuit board matching footprint/receiving holes.

### FINAL REMARKS

A particular application of the invention relating to a RF tuner module has been described. However, the invention is also applicable to others types of electronic module. Such an electronic module may have or may not have any connector.

The invention may find application in a wide range of electronic apparatuses, for example audio apparatus, video apparatus, photo apparatus, personal computer, etc . . .

While a particular example of an electronic module comprising mounting tags enabling to define two different heights has been described, it will be apparent for a person skilled in the art that an electronic module comprising mounting tags enabling more than two different heights is also possible by adding additional portions having different widths and defining additional abutments. For example, an electronic module may comprise mounting tags having four portions of different widths defining three abutments, or five portions of different widths defining four abutments, etc . . .

The drawings and their description hereinbefore illustrate rather than limit the invention.

Any reference sign in a claim should not be construed as limiting the claim. The word “comprising” does not exclude the presence of other elements than those listed in a claim. The word “a” or “an” preceding an element does not exclude the presence of a plurality of such element.

1. An electronic module comprising: a housing within which an electronic circuit resides, and a mounting tag for mounting the electronic module on a printed circuit board (PCB), wherein: the mounting tag comprises, from an end towards the housing, a first portion, a second portion and a third portion, the first portion has a first width inferior to a second width of the second portion so as to define a first abutment, which will come into contact with a printed circuit board (PCB) when the mounting tag is inserted in a hole of that printed circuit board having a hole width comprised between the first width and the second width, and the second width of the second portion is inferior to a third width of the third portion so as to define a second abutment, which will come into contact with a printed circuit board (PCB) when the mounting tag is inserted in a hole of that printed circuit board having a hole width comprised between the second width and the third width.

2. The electronic module according to claim 1, wherein the first abutment is substantially parallel to the printed circuit board (PCB).

3. The electronic module according to claim 1, wherein the second abutment is substantially parallel to the printed circuit board (PCB).

4. An The electronic module according to claim 1, wherein the mounting tag is provided on each corner of the housing.

5. An electronic module according to claim 1, wherein the housing further comprises a plurality of connecting pins and at least one connector coupled to the electronic circuit.

6. The electronic module according to claim 1, wherein the electronic module is a radiofrequency tuner module.

7. The electronic apparatus comprising an electronic module according to any claim 1 and a printed circuit board (PCB), the electronic module being horizontally mounted onto the printed circuit board (PCB).

8. A method of manufacturing an electronic apparatus comprising the step of: providing an electronic module, the electronic module comprising: a housing within which an electronic circuit resides and a mounting tag, the mounting tag comprises, from an end towards the housing, a first portion, a second portion, and a third portion, the first portion has a first width inferior to a second width of the second portion so as to define a first abutment, and the second width of the second portion is inferior to a third width of the third portion so as to define a second abutment, mounting the electronic module onto a printed circuit board (PCB) by: inserting the mounting tag in a hole of that printed circuit board having a hole width comprised between the first width and the second width until the first abutment come into contact with a top surface of that printed circuit board when manufacturing an electronic apparatus having a first characteristic dimension, inserting the mounting tag in a hole of that printed circuit board having a hole width comprised between the second width and the third width until the second abutment come into contact with a top surface of that printed circuit board when manufacturing an electronic apparatus having a second characteristic dimension.

9. The method of manufacturing an electronic apparatus according to claim 8, wherein the first characteristic dimension is a first gap height between the electronic module and the printed circuit board (PCB) and the second characteristic dimension is a second gap height between the electronic module and the printed circuit board (PCB).

10. The method of manufacturing an electronic apparatus according to claim 8, wherein the electronic module further comprises at least one connector, the first characteristic dimension is a first connector height and the second characteristic dimension is a second connector height.
